(19) United States
(12) Patent Application Publication
(10) Pub. No.: US 2026/0180562 A1
(43) Pub. Date: Jun. 25, 2026

(54) TRUE RANDOM NUMBER GENERATORS INCLUDING FIBONACCI-GALOIS RING OSCILLATORS WITH A STOCHASTIC START-UP CONDITION

(71) Applicant: Microsoft Technology Licensing, LLC, Redmond, WA (US)

(72) Inventor: Ting-Yen CHIANG, Palo Alto, CA (US)

(21) Appl. No.: 18/990,642

(22) Filed: Dec. 20, 2024

(51) Int. Cl. H03K 3/84; H03K 3/03

(52) U.S. Cl. CPC H03K 3/84; H03K 3/0315

(57) ABSTRACT

True random number generators including Fibonacci-Galois ring oscillators with a stochastic start-up condition are described. An example ring oscillator circuit includes a first oscillating loop comprising at least three inverter stages, where the first oscillating loop is configured to provide a start-up stochastic condition for starting oscillations in a second oscillating loop. The second oscillating loop comprises a chain of inverter stages and a plurality of switches whose state is determined by a feedback polynomial. The ring oscillator circuit is to: (1) during a first mode of operation, enable oscillations in the first oscillating loop while keeping the second oscillating loop open, and thereby generate the stochastic start-up condition for starting oscillations in the second oscillating loop, and (2) during a second mode of operation, enable oscillations in the second oscillating loop in response to the stochastic start-up condition, while keeping the first oscillating loop open.

### BACKGROUND

A true random number generator (TRNG) is a vital component in many cryptography and security applications. Many security processors include a true random number generator that relies upon the entropy (e.g., randomness) from the environment to generate the random numbers. The random numbers are used for generating keys by a respective processor (e.g., a specific security processor) or by security software executed by a processor. Cryptographic systems included in such processors rely on the unpredictability and the irreproducibility of digital keys that are used for encrypting and/or signing confidential information. The unpredictability and irreproducibility of digital keys depends upon the entropy from the environment (e.g., the variability among dies associated with the processors that are introduced as a result of semiconductor fabrication techniques). Therefore, ensuring robust entropy quality in the true random number generators is crucial. One way to ensure robust entropy is to use certain types of ring oscillators as part of the true random number generators.

True random number generators based on Fibonacci-Galois ring oscillators have gained significant attention because of their high throughput and entropy rate. However, such oscillators can suffer from periodic oscillations, which is the primary failure mechanism for such oscillators. Accordingly, there is a need for improvements to the ring oscillators implemented as part of the true random number generators.

### SUMMARY

In one example, the present disclosure relates to a ring oscillator circuit including a first oscillating loop comprising at least three inverter stages, where the first oscillating loop is configured to provide a start-up stochastic condition for starting oscillations in a second oscillating loop. The second oscillating loop comprises a chain of inverter stages and a plurality of switches whose state is determined by a feedback polynomial.

The ring oscillator circuit is to: (1) during a first mode of operation of the ring oscillator circuit, enable oscillations in the first oscillating loop while keeping the second oscillating loop open, and thereby generate the stochastic start-up condition for starting oscillations in the second oscillating loop, and (2) during a second mode of operation of the ring oscillator circuit, enable oscillations in the second oscillating loop in response to the stochastic start-up condition, while keeping the first oscillating loop open.

In another example, the present disclosure relates to a true random number generator circuit. The true random number generator circuit may include at least one Fibonacci ring oscillator circuit including a first oscillating loop comprising at least three inverter stages, where the first oscillating loop is configured to provide a first start-up stochastic condition for starting oscillations in a second oscillating loop. The second oscillating loop may comprise a first chain of inverter stages and a first plurality of switches whose state is determined by a first feedback polynomial.

The at least one Fibonacci ring oscillator circuit is to: (1) during a first mode of operation of the at least one Fibonacci ring oscillator circuit, enable oscillations in the first oscillating loop while keeping the second oscillating loop open, and thereby generate the stochastic start-up condition for starting oscillations in the second oscillating loop, and (2) during a second mode of operation of the at least one Fibonacci ring oscillator circuit, enable oscillations in the second oscillating loop in response to the first stochastic start-up condition, while keeping the first oscillating loop open.

The true random number generator circuit may further include at least one Galois ring oscillator circuit including a third oscillating loop comprising at least three inverter stages, where the third oscillating loop is configured to provide a second start-up stochastic condition for starting oscillations in a fourth oscillating loop. The fourth oscillating loop may comprise a second chain of inverter stages and a second plurality of switches whose state is determined by a second feedback polynomial.

The at least one Galois ring oscillator circuit is to: (1) during a first mode of operation of the at least one Galois ring oscillator circuit, enable oscillations in the third oscillating loop while keeping the fourth oscillating loop open, and thereby generate the second stochastic start-up condition for starting oscillations in the fourth oscillating loop, and (2) during a second mode of operation of the at least one Galois ring oscillator circuit, enable oscillations in the fourth oscillating loop in response to the second stochastic start-up condition, while keeping the third oscillating loop open.

In yet another example, the present disclosure relates to a method for operating a ring oscillator circuit comprising: (1) a first oscillating loop including at least three inverter stages, and (2) a second oscillating loop including a chain of inverter stages and a plurality of switches whose state is determined by a feedback polynomial. The method may include during a first mode of operation of the ring oscillator circuit, generating a stochastic start-up condition by enabling oscillations in the first oscillating loop while keeping the second oscillating loop open. The method may further include during a second mode of operation of the ring oscillator circuit, enabling oscillations in the second oscillating loop in response to the generated stochastic start-up condition, while keeping the first oscillating loop open.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 is a block diagram of an example ring oscillator circuit with a stochastic start-up condition for use with a true random number generator in accordance with one example;

FIG. 2 is a block diagram of another example ring oscillator circuit with a stochastic start-up condition for use with a true random number generator in accordance with one example;

FIG. 3 shows waveforms associated with ring oscillator circuits in accordance with one example;

FIG. 4 shows waveforms output from a true random number generator based on the example ring oscillator circuits shown in FIG. 1 and FIG. 2;

FIG. 5 shows an example true random number generator with the ring oscillator circuits described herein; and

FIG. 6 shows a flow chart of an example method for operating the ring oscillator circuits described with respect to FIGS. 1-4.

### DETAILED DESCRIPTION

Examples disclosed in the present disclosure relate to true random number generators including Fibonacci-Galois ring oscillators with a stochastic start-up condition. As noted earlier, a true random number generator (TRNG) is a vital component in many cryptography and security applications. Many security processors include a true random number generator that relies upon the entropy (e.g., randomness) from the environment to generate the random numbers. The random numbers are used for generating keys by a respective processor (e.g., a specific security processor) or by security software executed by a processor. Cryptographic systems included in such processors rely on the unpredictability and the irreproducibility of digital keys that are used for encrypting and/or signing confidential information. The unpredictability and irreproducibility of digital keys depends upon the entropy from the environment (e.g., the variability among dies associated with the processors that are introduced as a result of semiconductor fabrication techniques). Therefore, ensuring robust entropy quality in the true random number generators is crucial. One way to ensure robust entropy is to use certain types of ring oscillators as part of the true random number generators.

True random number generators based on Fibonacci-Galois Ring Oscillators have gained significant attention because of their high throughput and entropy rate. However, such oscillators can suffer from periodic oscillations, which is the primary failure mechanism for such oscillators. Periodic oscillations can result in periodic waveforms corresponding to the sampled data from the true random number generator. This in turn can make the numbers generated by the true random number generator less random. Accordingly, there is a need for improvements to the ring oscillators implemented as part of the true random number generators.

Broadly speaking, to address the issue of periodic oscillations, the present disclosure provides examples of true random number generators that include ring oscillators with a stochastic start-up condition. Given that the initial condition for starting the oscillation is crucial in determining the random number sequence, an unpredictable stochastic start-up condition for generating each random bit will eliminate concerns of periodic oscillation. The unpredictable stochastic start-up condition during each oscillation start-up will ensure high entropy quality as described herein.

In addition, in certain true random number generators the ring oscillator is allowed to oscillate indefinitely. This means that although during a relatively short time frame the numbers generated by the true random number generator may be truly random, over a longer time frame, the numbers may not be as random since the oscillations may become periodic over the longer time frame. The examples of ring oscillators described herein include stopping and re-starting of the oscillations, ensuring higher entropy for the true random number generators.

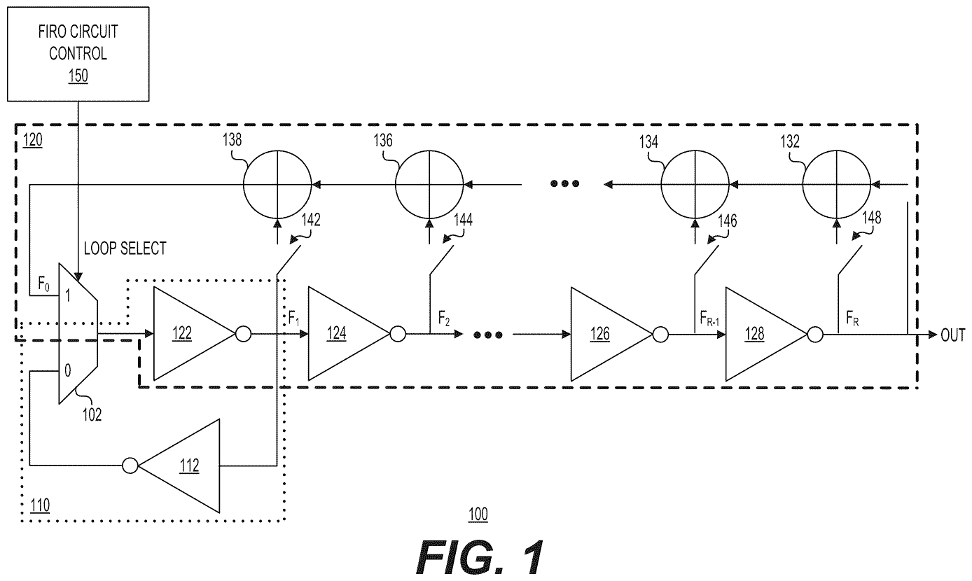

FIG. 1 is a block diagram of an example ring oscillator circuit 100 with a stochastic start-up condition for use with a true random number generator in accordance with one example. Ring oscillator circuit 100 includes a short oscillating loop 110 and a long oscillating loop 120. In this example, long oscillating loop 120 comprises a Fibonacci ring oscillator. Ring oscillator circuit 100 further includes a Fibonacci ring oscillator (FIRO) control circuit 150 that is configured to generate a control signal, labeled as LOOP SELECT. Depending upon the state of the LOOP SELECT signal, one or the other oscillating loops included in ring oscillator circuit 100 is oscillating. Ring oscillator circuit 100 further includes a multiplexer 102, which is configured to receive the control signal, labeled as LOOP SELECT.

Upon being powered up, ring oscillator circuit 100 is configured such that during a first operation cycle of ring oscillator circuit 100 (corresponding to a first mode of operation of the ring oscillator circuit 100), the short oscillating loop 110 starts oscillating. During this mode of operation, the long oscillating loop 120 is open, and thus is not oscillating. This initial set up is achieved by the FIRO control circuit 150 providing a logic 0 as the LOOP SELECT signal to multiplexer 102, which in turn ensures that while short oscillating loop 110 is operational, the long oscillating loop 120 is open. During a subsequent operation cycle (corresponding to a second mode of operation of the ring oscillator circuit 100), the FIRO control circuit 150 provides a logic 1 as the LOOP SELECT signal to multiplexer 102, which in turn ensures that while long oscillating loop 120 is operational, the short oscillating loop 110 is open. As described herein, the short oscillating loop 110 corresponds to the ring oscillator loop that is used to generate the start-up condition. As described herein, the long oscillating loop 120 corresponds to the ring oscillator loop whose output is sampled to generate the random bits for a true random number generator.

With continued reference to FIG. 1, short oscillating loop 110 includes inverter stage 112 and inverter stage 122. Each inverter stage can comprise multiple inverters that are coupled in series. The inverters, when connected in a loop fashion, operate as a ring oscillator. Long oscillating loop 120 is implemented as a Fibonacci ring oscillator (FIRO). In this example, the long oscillating loop 120 includes several inverter stages and exclusive-OR gates that are configured to work with several switches controlled by a polynomial. Long oscillating loop 120 includes multiple inverter stages (e.g., inverter stages 122, 124, 126, and 128). In one example, the number of inverter stages in long oscillating loop 120 should be a prime number. Each inverter stage can comprise multiple inverters that are coupled in series. Long oscillating loop 120 further includes multiple exclusive-OR gates (e.g., exclusive-OR gates 132, 134, 136, and 138). Long oscillating loop 120 further includes multiple switches (e.g., switches 142, 144, 146, and 148). The switches are controlled by bits associated with the polynomial for the Fibonacci ring oscillator. Any of the example polynomials shown in Table 1 below can be used with the Fibonacci ring oscillator.

TABLE 1
${p}_{0}^{F} ( x ) = 1 + x + {x}^{2} + {x}^{3} + {x}^{5} + {x}^{6} + {x}^{7} + {x}^{8} + {x}^{9} + {x}^{10}$
${p}_{1}^{F} ( x ) = 1 + x + {x}^{2} + {x}^{3} + {x}^{4} + {x}^{6} + {x}^{7} + {x}^{10}$
${p}_{2}^{F} ( x ) = 1 + x + {x}^{2} + {x}^{3} + {x}^{4} + {x}^{5} + {x}^{6} + {x}^{10}$
${p}_{3}^{F} ( x ) = 1 + x + {x}^{2} + {x}^{3} + {x}^{4} + {x}^{5} + {x}^{6} + {x}^{7} + {x}^{9} + {x}^{10}$

Still referring to FIG. 1, FIRO control circuit 150 may include finite state machines, registers, and other types of logic configured to provide the LOOP SELECT signal to multiplexer 102. In addition, FIRO control circuit 150 can receive a clock signal that allows it to provide control signals, such as the LOOP SELECT signal, in relation to a time reference. Additional operational aspects of the ring oscillator circuit 100 are explained with the help of waveforms described later. Although FIG. 1 shows ring oscillator circuit 100 as having certain components that are arranged in a certain manner, ring oscillator circuit 100 may include additional or fewer components that are arranged differently.

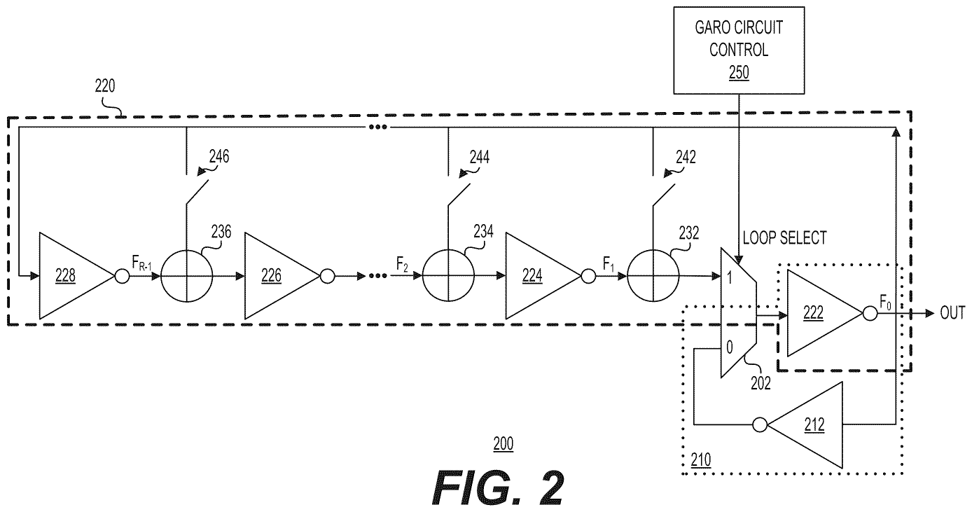

FIG. 2 is a block diagram of another example ring oscillator circuit 200 with a stochastic start-up condition for use with a true random number generator in accordance with one example. Ring oscillator circuit 200 includes a short oscillating loop 210 and a long oscillating loop 220. In this example, long oscillating loop 220 comprises a Galois ring oscillator. Ring oscillator circuit 200 further includes a Galois ring oscillator (GARO) control circuit 250 that is configured to generate a control signal, labeled as LOOP SELECT. Depending upon the state of the LOOP SELECT signal, one or the other oscillating loop included in ring oscillator circuit 200 is oscillating. Ring oscillator circuit 200 further includes a multiplexer 202, which is configured to receive the control signal, labeled as LOOP SELECT.

Upon being powered up, ring oscillator circuit 200 is configured such that during a first operation cycle of ring oscillator circuit 200 (corresponding to a first mode of operation of the ring oscillator circuit 200), the short oscillating loop 210 starts oscillating. During this mode of operation, the long oscillating loop 220 is open, and thus is not oscillating. This initial set up is achieved by the GARO control circuit 250 providing a logic 0 as the LOOP SELECT signal to multiplexer 202, which in turn ensures that while short oscillating loop 210 is operational, the long oscillating loop 220 is open. During a subsequent operation cycle (corresponding to a second mode of operation of the ring oscillator circuit 100), the GARO control circuit 250 provides a logic 1 as the LOOP SELECT signal to multiplexer 202, which in turn ensures that while long oscillating loop 220 is operational, the short oscillating loop 210 is open. As noted earlier, as described herein, the short oscillating loop 210 corresponds to the ring oscillator loop that is used to generate the start-up condition. As noted earlier, as described herein, the long oscillating loop 220 corresponds to the ring oscillator loop whose output is sampled to generate the random bits for a true random number generator.

With continued reference to FIG. 2, short oscillating loop 210 includes inverter stage 212 and inverter stage 222. Each inverter stage can comprise multiple inverters that are coupled in series. The inverters, when connected in a loop fashion, operate as a ring oscillator. Long oscillating loop 220 is implemented as a Galois ring oscillator (GARO). In this example, the long oscillating loop 220 includes several inverter stages and exclusive-OR gates that are configured to work with several switches controlled by a polynomial. Long oscillating loop 220 includes multiple inverter stages (e.g., inverter stages 222, 224, 226, and 228). In one example, the number of inverter stages in long oscillating loop 220 should be a prime number. Each inverter stage can comprise multiple inverters that are coupled in series. Long oscillating loop 220 further includes multiple exclusive-OR gates (e.g., exclusive-OR gates 232, 234, and 236). Long oscillating loop 220 further includes multiple switches (e.g., switches 242, 244, and 248). The switches are controlled by bits associated with the polynomial for the Galois ring oscillator. Any of the example polynomials shown in Table 2 below can be used with the Galois ring oscillator.

TABLE 2
${p}_{0}^{G} ( x ) = 1 + {x}^{2} + {x}^{3} + {x}^{5} + {x}^{6} + {x}^{7} + {x}^{9} + {x}^{11}$
${p}_{1}^{G} ( x ) = 1 + {x}^{2} + {x}^{3} + {x}^{5} + {x}^{6} + {x}^{7} + {x}^{8} + {x}^{11}$
${p}_{2}^{G} ( x ) = 1 + {x}^{2} + {x}^{3} + {x}^{4} + {x}^{5} + {x}^{7} + {x}^{9} + {x}^{11}$
${p}_{3}^{G} ( x ) = 1 + {x}^{2} + {x}^{3} + {x}^{4} + {x}^{5} + {x}^{6} + {x}^{9} + {x}^{11}$

Still referring to FIG. 2, GARO control circuit 250 may include finite state machines, registers, and other types of logic configured to provide the LOOP SELECT signal to multiplexer 202. In addition, GARO control circuit 250 can receive a clock signal that allows it to provide control signals, such as the LOOP SELECT signal, in relation to a time reference. Additional operational aspects of the ring oscillator circuit 200 are explained with the help of waveforms described later. Although FIG. 2 shows ring oscillator circuit 200 as having certain components that are arranged in a certain manner, ring oscillator circuit 200 may include additional or fewer components that are arranged differently.

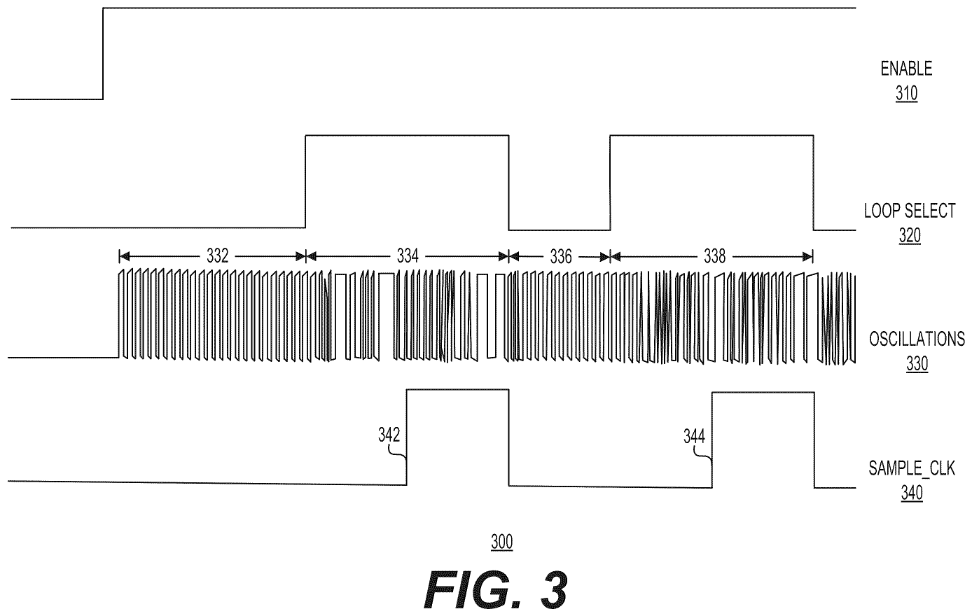

FIG. 3 shows waveforms 300 associated with ring oscillator circuits in accordance with one example. Example waveforms 300 show the behavior of various signals, in relation to time, that are associated with the ring oscillators described herein. ENABLE waveform 310 corresponds to a signal that can be used to enable the ring oscillator circuit. As shown in FIG. 3, this signal is asserted to enable the operation cycles for each of the two different modes of operation of the ring oscillator circuit. The LOOP SELECT waveform 320 corresponds to the LOOP SELECT signal described earlier with respect to FIG. 1 and FIG. 2. As explained earlier, the LOOP SELECT signal allows a control circuit associated with the ring oscillator circuit to allow it to operate in one of two modes. A first mode is a mode of operation in which the short oscillating loop (e.g., the short oscillating loop 110 of FIG. 1 or the short oscillating loop 210 of FIG. 2) is oscillating while the long oscillating loop (e.g., the long oscillating loop 120 of FIG. 1 or the long oscillating loop 220 of FIG. 2) is open, and thus is not oscillating. A second mode is a mode of operation in which the short oscillating loop (e.g., the short oscillating loop 110 of FIG. 1 or the short oscillating loop 210 of FIG. 2) is open, and thus is not oscillating, while the long oscillating loop (e.g., the long oscillating loop 120 of FIG. 1 or the long oscillating loop 220 of FIG. 2) is oscillating.

With continued reference to FIG. 3, OSCILLATIONS waveform 330 shows the oscillation waveforms for the short oscillating loop and the long oscillating loop, respectively. In this example, portion 332 of the OSCILLATIONS waveform 330 corresponds to the oscillations output by the short oscillating loop. Portion 334 of the OSCILLATIONS waveform 330 corresponds to the oscillations output by the long oscillating loop. Portion 336 of the OSCILLATIONS waveform 330 corresponds to the oscillations output by the short oscillating loop. Portion 338 of the OSCILLATIONS waveform 330 corresponds to the oscillations output by the long oscillating loop. A ring oscillator control circuit (e.g., FIRO control circuit 150 of FIG. 1 or GARO control circuit 250 of FIG. 2) is configured to keep operating the ring oscillator circuit in these alternating modes until the ring oscillator circuit is turned off or reset otherwise.

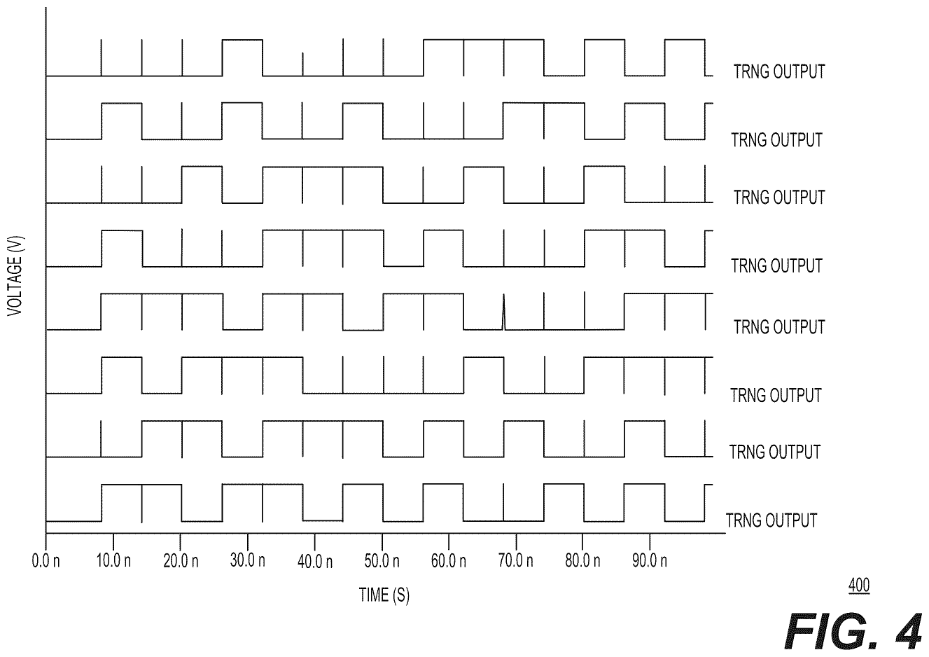

SAMPLE_CLK waveform 340 corresponds to the sampling clock used to sample an output of the ring oscillator circuit. In this example, a rising edge 342 of the SAMPLE_CLK waveform 340 is used to generate a random bit from the oscillations associated with the long oscillating loop. In addition, another rising edge 344 of the SAMPLE_CLK waveform 340 is used to generate a subsequent random bit from the oscillations associated with the long oscillating loop. Falling edges can also be used for sampling. As one can see from the waveforms 400 of FIG. 4, during the transition from a case in which the short oscillating loop is oscillating to the case in which the long oscillating loop is oscillating, there is a transition. Every time this transition happens, the starting phase is different, which ensures that the start-up stochastic condition will also be unpredictable. Advantageously, having a different and an unpredictable start-up stochastic condition removes any concerns with periodic oscillations in the ring oscillator circuits described herein. Moreover, as needed, the sampling frequency can be varied. In addition, as needed, the specific edge of the clock (e.g., SAMPLE_CLK waveform 340) that is used for sampling can be moved by introducing random delays.

FIG. 4 shows waveforms 400 output from a true random number generator based on the example ring oscillator circuits shown in FIG. 1 and FIG. 2. As described earlier, to address the issue of periodic oscillations, the present disclosure provides examples of true random number generators that include ring oscillator circuits (e.g., ring oscillator circuit 100 of FIG. 1 and ring oscillator circuit 200 of FIG. 2) with a stochastic start-up condition. Given that the initial condition for starting the oscillation is crucial in determining the random number sequence, an unpredictable stochastic start-up condition for generating each random bit will eliminate concerns associated with periodic oscillations. Waveforms 400 show output random number sequences that are generated after each restart of the true random number generator. From the waveforms 400, it is evident that the output of the true random number generator is not deterministic; instead, each of the sequences is different. Advantageously, the unpredictable stochastic start-up condition during each oscillation start-up ensures a high entropy quality for the true random number generators described herein.

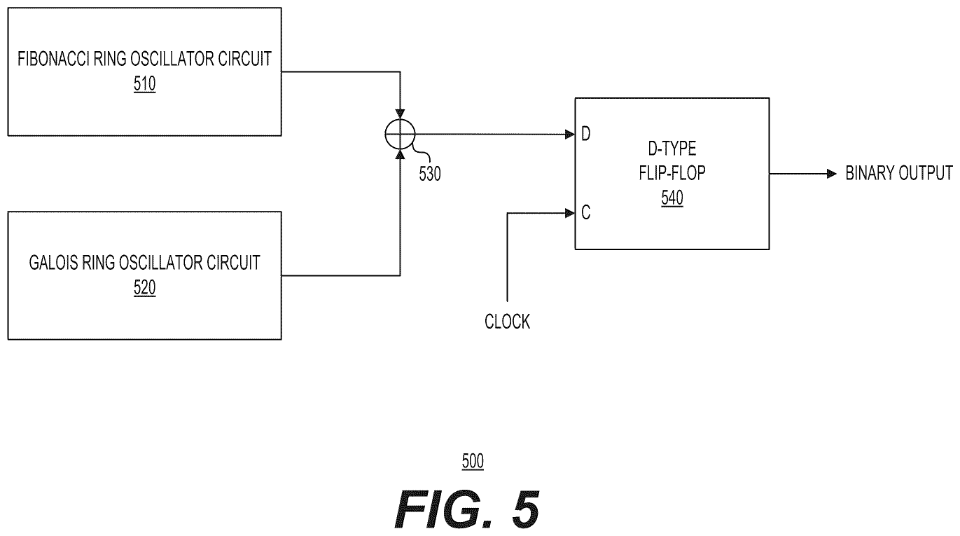

FIG. 5 shows an example true random number generator 500 with the ring oscillator circuits described herein. True random number generator 500 combines the properties of the ring oscillator circuits described earlier with respect to FIG. 1 and FIG. 2, by including both a Fibonacci ring oscillator circuit 510 and a Galois ring oscillator circuit 520. Multiple such oscillator circuits can also be included. The lengths of the two ring oscillator circuits (e.g., Fibonacci ring oscillator circuit 510 and Galois ring oscillator circuit 520) should preferably be mutually prime. This configuration maximizes the period of the random number sequence, while minimizing the interlocking and coupling effects. The Fibonacci ring oscillator circuit 510 includes: (1) a short oscillating loop (e.g., similar to short oscillating loop 110 of FIG. 1) comprising at least three inverter stages, where the short oscillating loop is configured to provide a first start-up stochastic condition for starting oscillations in a long oscillating loop (e.g., similar to long oscillating loop 120 of FIG. 1). The long oscillating loop comprises a chain of inverter stages and a plurality of switches whose state is determined by a feedback polynomial. Similar to as described earlier with respect to FIG. 1, the Fibonacci ring oscillator circuit 510 is configured to: (1) during a first mode of operation, enable oscillations in the short oscillating loop while keeping the long oscillating loop open, and thereby generate the stochastic start-up condition for starting oscillations in the long oscillating loop, and (2) during a second mode of operation, enable oscillations in the long oscillating loop in response to the stochastic start-up condition, while keeping the short oscillating loop open.

With continued reference to FIG. 5, the Galois ring oscillator circuit 520 includes: (1) an oscillating loop (e.g., similar to short oscillating loop 210 of FIG. 2) comprising at least three inverter stages, where the oscillating loop is configured to provide a second start-up stochastic condition for starting oscillations in another oscillating loop (e.g., similar to long oscillating loop 220 of FIG. 2). The long oscillating loop also comprises a chain of inverter stages and a plurality of switches whose state is determined by a feedback polynomial. Similar to as described earlier with respect to FIG. 2, the Galois ring oscillator circuit 520 is configured to: (1) during the first mode of operation, enable oscillations in the short oscillating loop while keeping the long oscillating loop open, and thereby generate the second stochastic start-up condition for starting oscillations in the long oscillating loop, and (2) during the second mode of operation, enable oscillations in the long oscillating loop in response to the second stochastic start-up condition, while keeping the short oscillating loop open.

Still referring to FIG. 5, true random number generator 500 further includes an exclusive OR gate 530 for: (1) receiving a first output from the Fibonacci ring oscillator circuit 510, (2) receiving a second output from the Galois ring oscillator circuit 520, and (3) providing an output. The output of the exclusive OR gate 530 is coupled to a D-type flip-flop 540. The D-type flip-flop 540 also receives a clock signal. In response to receiving the output from the exclusive OR gate, D-type flip-flop 540 generates a binary output comprising random bits corresponding to a random number. Although FIG. 5 shows true random number generator 500 as having certain components that are arranged in a certain manner, true random number generator 500 may include additional or fewer components that are arranged differently.

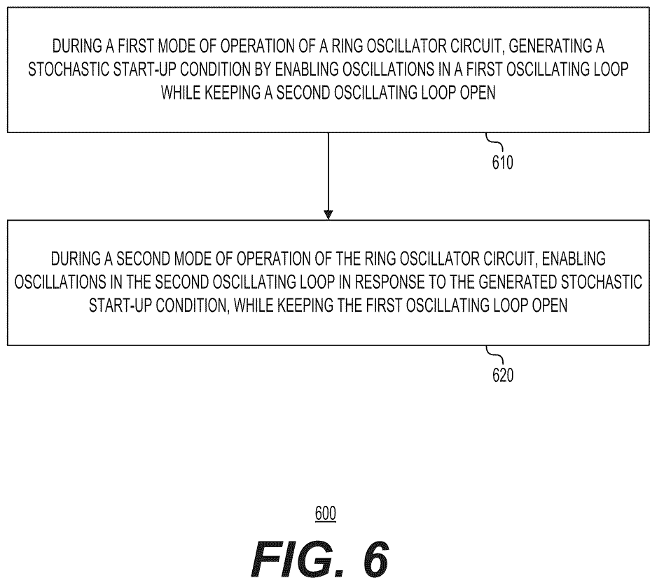

FIG. 6 shows a flow chart of an example method for operating the ring oscillator circuits described herein. In one example, the ring oscillator circuit corresponds to ring oscillator circuit 100 of FIG. 1. Alternatively, the ring oscillator circuit corresponds to ring oscillator circuit 200 of FIG. 2, or a combination of such ring oscillator circuits. Step 610 includes during a first mode of operation of the ring oscillator circuit, generating a stochastic start-up condition by enabling oscillations in the first oscillating loop while keeping the second oscillating loop open.

As an example, as part of this step, the first oscillating loop may correspond to short oscillating loop 110 of FIG. 1 or short oscillating loop 210 of FIG. 2. As described with respect to FIGS. 1-3, the LOOP SELECT signal can be used to control a multiplexer, which in turn allows one to keep the first oscillating loop operational while the second oscillating loop is open. With respect to FIG. 3, the first mode of operation corresponds to oscillations shown in portion 332 and portion 336 of OSCILLATION waveform 330.

Step 620 includes during a second mode of operation of the ring oscillator circuit, enabling oscillations in the second oscillating loop in response to the generated stochastic start-up condition, while keeping the first oscillating loop open. As an example, as part of this step, the second oscillating loop may correspond to long oscillating loop 120 of FIG. 1 or long oscillating loop 220 of FIG. 2. As described with respect to FIGS. 1-3, the LOOP SELECT signal can be used to control a multiplexer, which in turn allows one to keep the second oscillating loop operational while the first oscillating loop is open. With respect to FIG. 3, the second mode of operation corresponds to oscillations shown in portion 334 and portion 338 of OSCILLATION waveform 330. Advantageously, the start-up stochastic condition comprises an unpredictable stochastic start-up condition, allowing for a generation of a respective random bit by a true random number generator incorporating the ring oscillator circuit.

In conclusion, the present disclosure relates to a ring oscillator circuit including a first oscillating loop comprising at least three inverter stages, where the first oscillating loop is configured to provide a start-up stochastic condition for starting oscillations in a second oscillating loop. The second oscillating loop comprises a chain of inverter stages and a plurality of switches whose state is determined by a feedback polynomial.

The ring oscillator circuit is to: (1) during a first mode of operation of the ring oscillator circuit, enable oscillations in the first oscillating loop while keeping the second oscillating loop open, and thereby generate the stochastic start-up condition for starting oscillations in the second oscillating loop, and (2) during a second mode of operation of the ring oscillator circuit, enable oscillations in the second oscillating loop in response to the stochastic start-up condition, while keeping the first oscillating loop open.

The ring oscillator circuit may further include a ring oscillator control circuit to generate a control signal to: (1) during the first mode of operation, enable oscillations in the first oscillating loop for a first duration, and (2) during the second mode of operation, enable oscillations in the second oscillating loop for a second duration, different from the first duration. The ring oscillator circuit may further include a multiplexer having a first input terminal, a second input terminal, and an output terminal, and where the multiplexer is configured to selectively couple the first input terminal to the output terminal or the second input terminal to the output terminal based on a state of the control signal generated by the ring oscillator control circuit. The state of the control signal, generated by the ring oscillator control circuit, may determine which one of the first oscillating loop or the second oscillating loop is open.

The start-up stochastic condition may comprise an unpredictable stochastic start-up condition, allowing for a generation of a respective random bit by a true random number generator incorporating the ring oscillator circuit. The second oscillating loop may correspond to a Fibonacci ring oscillator circuit. Alternatively, the second oscillating loop may correspond to a Galois ring oscillator circuit.

In another example, the present disclosure relates to a true random number generator circuit. The true random number generator circuit may include at least one Fibonacci ring oscillator circuit including a first oscillating loop comprising at least three inverter stages, where the first oscillating loop is configured to provide a first start-up stochastic condition for starting oscillations in a second oscillating loop. The second oscillating loop may comprise a first chain of inverter stages and a first plurality of switches whose state is determined by a first feedback polynomial.

The at least one Fibonacci ring oscillator circuit is to: (1) during a first mode of operation of the at least one Fibonacci ring oscillator circuit, enable oscillations in the first oscillating loop while keeping the second oscillating loop open, and thereby generate the stochastic start-up condition for starting oscillations in the second oscillating loop, and (2) during a second mode of operation of the at least one Fibonacci ring oscillator circuit, enable oscillations in the second oscillating loop in response to the first stochastic start-up condition, while keeping the first oscillating loop open.

The true random number generator circuit may further include at least one Galois ring oscillator circuit including a third oscillating loop comprising at least three inverter stages, where the third oscillating loop is configured to provide a second start-up stochastic condition for starting oscillations in a fourth oscillating loop. The fourth oscillating loop may comprise a second chain of inverter stages and a second plurality of switches whose state is determined by a second feedback polynomial.

The at least one Galois ring oscillator circuit is to: (1) during a first mode of operation of the at least one Galois ring oscillator circuit, enable oscillations in the third oscillating loop while keeping the fourth oscillating loop open, and thereby generate the second stochastic start-up condition for starting oscillations in the fourth oscillating loop, and (2) during a second mode of operation of the at least one Galois ring oscillator circuit, enable oscillations in the fourth oscillating loop in response to the second stochastic start-up condition, while keeping the third oscillating loop open.

The true random number generator circuit may further include an exclusive OR gate for: (1) receiving a first output from the at least one Fibonacci ring oscillator circuit, (2) receiving a second output from the at least one Galois ring oscillator circuit, and (3) providing a third output. The true random number generator circuit may further include a flip-flop circuit to receive the third output and generate a binary output comprising random bits corresponding to a random number.

The true random number generator circuit may further include (1) a Fibonacci ring oscillator control circuit to generate a first control signal to: (a) during the first mode of operation of the at least one Fibonacci ring oscillator circuit, enable oscillations in the first oscillating loop for a first duration, (b) during the second mode of operation of the at least one Fibonacci ring oscillator circuit, enable oscillations in the second oscillating loop for a second duration, different from the first duration. The true random number generator circuit may further include a Galois ring oscillator control circuit to generate a second control signal to: (a) during the first mode of operation of the at least one Galois ring oscillator circuit, enable oscillations in the third oscillating loop for the first duration, (b) during the second mode of operation of the at least one Galois ring oscillator circuit, enable oscillations in the fourth oscillating loop for the second duration. Each of the first start-up stochastic condition and the second start-up stochastic condition may comprise an unpredictable stochastic start-up condition, allowing for a generation of a respective random bit by the true random number generator circuit.

In yet another example, the present disclosure relates to a method for operating a ring oscillator circuit comprising: (1) a first oscillating loop including at least three inverter stages, and (2) a second oscillating loop including a chain of inverter stages and a plurality of switches whose state is determined by a feedback polynomial. The method may include during a first mode of operation of the ring oscillator circuit, generating a stochastic start-up condition by enabling oscillations in the first oscillating loop while keeping the second oscillating loop open. The method may further include during a second mode of operation of the ring oscillator circuit, enabling oscillations in the second oscillating loop in response to the generated stochastic start-up condition, while keeping the first oscillating loop open.

The method may further include, during the first mode of operation of the ring oscillator circuit, using a ring oscillator control circuit to enable oscillations in the first oscillating loop for a first duration. The method may further include, during the second mode of operation of the ring oscillator circuit, using the ring oscillator control circuit to enable oscillations in the second oscillating loop for a second duration, different from the first duration.

The ring oscillator circuit may further comprise a multiplexer having a first input terminal, a second input terminal, and an output terminal, and where the multiplexer is configured to selectively couple the first input terminal to the output terminal or the second input terminal to the output terminal based on a state of the control signal generated by the ring oscillator control circuit. The start-up stochastic condition may comprise an unpredictable stochastic start-up condition, allowing for a generation of a respective random bit by a true random number generator incorporating the ring oscillator circuit.

The second oscillating loop may correspond to a Fibonacci ring oscillator. Alternatively, the second oscillating loop may correspond to a Galois ring oscillator. The method may further include generating random bits for use with a true random number generator by operating the ring oscillator circuit.

It is to be understood that the methods, modules, and components depicted herein are merely exemplary. Alternatively, or in addition, the functionality described herein can be performed, at least in part, by one or more hardware logic components. For example, and without limitation, illustrative types of hardware logic components that can be used include Field-Programmable Gate Arrays (FPGAs), Application-Specific Integrated Circuits (ASICs), Application-Specific Standard Products (ASSPs), System-on-a-Chip systems (SOCs), or Complex Programmable Logic Devices (CPLDs). In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality.

The functionality associated with some examples described in this disclosure can also include instructions stored in a non-transitory media. The term “non-transitory media” as used herein refers to any media storing data and/or instructions that cause a machine to operate in a specific manner. Exemplary non-transitory media include non-volatile media and/or volatile media. Non-volatile media include, for example, a hard disk, a solid state drive, a magnetic disk or tape, an optical disk or tape, a flash memory, an EPROM, NVRAM, PRAM, or other such media, or networked versions of such media. Volatile media include, for example, dynamic memory, such as, DRAM, SRAM, a cache, or other such media. Non-transitory media is distinct from, but can be used in conjunction with transmission media. Transmission media is used for transferring data and/or instruction to or from a machine. Exemplary transmission media, include coaxial cables, fiber-optic cables, copper wires, and wireless media, such as radio waves.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed:

1. A ring oscillator circuit comprising:
a first oscillating loop comprising at least three inverter stages, wherein the first oscillating loop is configured to provide a start-up stochastic condition for starting oscillations in a second oscillating loop; and
wherein the second oscillating loop comprises a chain of inverter stages and a plurality of switches whose state is determined by a feedback polynomial, wherein the ring oscillator circuit is to: (1) during a first mode of operation of the ring oscillator circuit, enable oscillations in the first oscillating loop while keeping the second oscillating loop open, and thereby generate the stochastic start-up condition for starting oscillations in the second oscillating loop, and (2) during a second mode of operation of the ring oscillator circuit, enable oscillations in the second oscillating loop in response to the stochastic start-up condition, while keeping the first oscillating loop open.

2. The ring oscillator circuit of claim 1, further comprising a ring oscillator control circuit to generate a control signal to: (1) during the first mode of operation, enable oscillations in the first oscillating loop for a first duration, and (2) during the second mode of operation, enable oscillations in the second oscillating loop for a second duration, different from the first duration.

3. The ring oscillator circuit of claim 2, further comprising a multiplexer having a first input terminal, a second input terminal, and an output terminal, and wherein the multiplexer is configured to selectively couple the first input terminal to the output terminal or the second input terminal to the output terminal based on a state of the control signal generated by the ring oscillator control circuit.

4. The ring oscillator circuit of claim 3, wherein the state of the control signal generated by the ring oscillator control circuit determines which one of the first oscillating loop or the second oscillating loop is open.

5. The ring oscillator circuit of claim 1, wherein the start-up stochastic condition comprises an unpredictable stochastic start-up condition, allowing for a generation of a respective random bit by a true random number generator incorporating the ring oscillator circuit.

6. The ring oscillator circuit of claim 1, wherein the second oscillating loop corresponds to a Fibonacci ring oscillator circuit.

7. The ring oscillator circuit of claim 1, wherein the second oscillating loop corresponds to a Galois ring oscillator circuit.

8. A true random number generator circuit comprising:
at least one Fibonacci ring oscillator circuit including a first oscillating loop comprising at least three inverter stages, wherein the first oscillating loop is configured to provide a first start-up stochastic condition for starting oscillations in a second oscillating loop, wherein the second oscillating loop comprises a first chain of inverter stages and a first plurality of switches whose state is determined by a first feedback polynomial, wherein the at least one Fibonacci ring oscillator circuit is to: (1) during a first mode of operation of the at least one Fibonacci ring oscillator circuit, enable oscillations in the first oscillating loop while keeping the second oscillating loop open, and thereby generate the stochastic start-up condition for starting oscillations in the second oscillating loop, and (2) during a second mode of operation of the at least one Fibonacci ring oscillator circuit, enable oscillations in the second oscillating loop in response to the first stochastic start-up condition, while keeping the first oscillating loop open; and
at least one Galois ring oscillator circuit including a third oscillating loop comprising at least three inverter stages, wherein the third oscillating loop is configured to provide a second start-up stochastic condition for starting oscillations in a fourth oscillating loop, wherein the fourth oscillating loop comprises a second chain of inverter stages and a second plurality of switches whose state is determined by a second feedback polynomial, wherein the at least one Galois ring oscillator circuit is to: (1) during a first mode of operation of the at least one Galois ring oscillator circuit, enable oscillations in the third oscillating loop while keeping the fourth oscillating loop open, and thereby generate the second stochastic start-up condition for starting oscillations in the fourth oscillating loop, and (2) during a second mode of operation of the at least one Galois ring oscillator circuit, enable oscillations in the fourth oscillating loop in response to the second stochastic start-up condition, while keeping the third oscillating loop open.

9. The true random number generator circuit of claim 8, further comprising an exclusive OR gate for: (1) receiving a first output from the at least one Fibonacci ring oscillator circuit, (2) receiving a second output from the at least one Galois ring oscillator circuit, and (3) providing a third output.

10. The true random number generator circuit of claim 9, further comprising a flip-flop circuit to receive the third output and generate a binary output comprising random bits corresponding to a random number.

11. The true random number generator circuit of claim 8, further comprising: (1) a Fibonacci ring oscillator control circuit to generate a first control signal to: (a) during the first mode of operation of the at least one Fibonacci ring oscillator circuit, enable oscillations in the first oscillating loop for a first duration, (b) during the second mode of operation of the at least one Fibonacci ring oscillator circuit, enable oscillations in the second oscillating loop for a second duration, different from the first duration, (2) a Galois ring oscillator control circuit to generate a second control signal to: (a) during the first mode of operation of the at least one Galois ring oscillator circuit, enable oscillations in the third oscillating loop for the first duration, (b) during the second mode of operation of the at least one Galois ring oscillator circuit, enable oscillations in the fourth oscillating loop for the second duration.

12. The true random number generator circuit of claim 8, wherein each of the first start-up stochastic condition and the second start-up stochastic condition comprises an unpredictable stochastic start-up condition, allowing for a generation of a respective random bit by the true random number generator circuit.

13. A method for operating a ring oscillator circuit comprising: (1) a first oscillating loop including at least two inverter stages, and (2) a second oscillating loop including a chain of inverter stages and a plurality of switches whose state is determined by a feedback polynomial, the method comprising:
during a first mode of operation of the ring oscillator circuit, generating a stochastic start-up condition by enabling oscillations in the first oscillating loop while keeping the second oscillating loop open; and
during a second mode of operation of the ring oscillator circuit, enabling oscillations in the second oscillating loop in response to the generated stochastic start-up condition, while keeping the first oscillating loop open.

14. The method of claim 13, further comprising, during the first mode of operation of the ring oscillator circuit, using a ring oscillator control circuit to enable oscillations in the first oscillating loop for a first duration.

15. The method of claim 14, further comprising, during the second mode of operation of the ring oscillator circuit, using the ring oscillator control circuit to enable oscillations in the second oscillating loop for a second duration, different from the first duration.

16. The method of claim 15, wherein the ring oscillator circuit further comprises a multiplexer having a first input terminal, a second input terminal, and an output terminal, and wherein the multiplexer is configured to selectively couple the first input terminal to the output terminal or the second input terminal to the output terminal based on a state of the control signal generated by the ring oscillator control circuit.

17. The method of claim 13, wherein the start-up stochastic condition comprises an unpredictable stochastic start-up condition, allowing for a generation of a respective random bit by a true random number generator incorporating the ring oscillator circuit.

18. The method of claim 13, wherein the second oscillating loop corresponds to a Fibonacci ring oscillator.

19. The method of claim 13, wherein the second oscillating loop corresponds to a Galois ring oscillator.

20. The method of claim 13, further comprising generating random bits for use with a true random number generator by operating the ring oscillator circuit.
